(19) United States
(12) Patent Application Publication
(10) Pub. No.: US 2026/0261199 A1
(43) Pub. Date: Sep. 3, 2026

(54) POWER ON/OFF MODULE

(71) Applicant: SHANGHAI XINLONG SEMICONDUCTOR TECHNOLOGY CO., LTD., Pudong New Area, Shanghai (CN)

(72) Inventors: Jinlong XU, Shanghai (CN); Ruiping LI, Shanghai (CN)

(73) Assignee: SHANGHAI XINLONG SEMICONDUCTOR TECHNOLOGY CO., LTD., Pudong New Area, Shanghai (CN)

(21) Appl. No.: 18/995,635

(22) PCT Filed: May 27, 2024
(86) PCT No.: PCT/CN2024/095434

§ 371 Date: Jan. 16, 2025

(30) Foreign Application Priority Data
Jun. 16, 2023 (CN) 202310713633.6

(51) Int. Cl. H02M 1/36; H02M 3/157; H03K 17/687

(52) U.S. Cl. CPC H02M 1/36; H02M 3/157; H03K 17/6871

(57) ABSTRACT

The present invention provides a power on/off module including a power on/off enable terminal, a startup sub-module and an enable voltage comparison sub-module. The startup sub-module determines, at both a low level of accuracy and a low level of power consumption, whether a signal at the power on/off enable terminal satisfies a power-on condition, and starts or stops supplying power to other modules according to predefined logic. The enable voltage comparison sub-module, when powered on, determines at a high level of accuracy whether the signal at the power on/off enable terminal satisfies the power-on condition, and activates or deactivates the other modules according to the predefined logic. Standby power consumption of the startup sub-module is lower than a minimum level of power consumption necessary for normal operation of the enable voltage comparison sub-module. In this way, the operational characteristics of the individual sub-modules are sensibly exploited to achieve a good tradeoff between power-off power consumption and response accuracy that the prior art fails to provide.

### TECHNICAL FIELD

The present invention relates to the field of integrated circuit (IC) technology, and particularly to a power on/off module.

### BACKGROUND

Electrical appliances used in our daily life all have a standby function, which is required to consume electrical power as little as possible in a standby mode and respond to a power-on control signal as accurately as possible.

If a product consumes much power after it is shut down or when it is standing by, it tends to lose some competitiveness and is probably placed at a disadvantage in commercial competition due to this. For battery-powered equipment, since the power system would be always in contact with both terminals of the battery, if there is a large current in the system after it is shut down, the battery will run out after a limited period of time. This may also cause a loss of competitiveness.

Inaccurate response to a power-on control signal tends to means unsatisfactory control for some particular applications.

Conventionally, this is typically solved by always maintaining a current in a module involved in making a power-on decision all the time, enabling the module to respond to an enable signal at any time with sufficient accuracy. However, in this design, there will be a current of several microamperes (μA) in the circuit even when it is in a powered off mode.

Therefore, the prior art fails to provide both low power consumption and accurate response to a power-on signal in a powered off mode.

### SUMMARY

It is an objective of the present invention to provide a power on/off module, which overcomes the above-described problem with the prior art, i.e., it fails to provide both low power consumption and accurate response to a power-on signal in a powered off mode.

To this end, the present invention provides a power on/off module used in circuitry including the power on/off module and functional modules. The power on/off module includes a power on/off enable terminal, a startup sub-module and an enable voltage comparison sub-module.

The startup sub-module is configured to obtain an external power supply.

The startup sub-module determines at a first level of accuracy whether a signal at the power on/off enable terminal satisfies a first power-on condition. If the first power-on condition is satisfied, it converts the external power supply into an internal power supply for directly or indirectly driving the enable voltage comparison sub-module and the functional modules to cause them to be powered on. If the first power-on condition is unsatisfied, it directly or indirectly cuts off power to the enable voltage comparison sub-module and the functional modules.

The enable voltage comparison sub-module, once powered on, determines at a second level of accuracy whether the signal at the power on/off enable terminal satisfies a second power-on condition. If the second power-on condition is satisfied, it outputs a control signal for driving at least some of the functional modules to cause them to be powered on. If the second power-on condition is unsatisfied, it outputs a control signal for driving at least some of the functional modules to cause them not to be powered on or remain off.

When the first power-on condition is not satisfied, the startup sub-module delivers its determination function at a first level of power consumption. The enable voltage comparison sub-module, when powered on, delivers its determination function at a second level of power consumption.

The first level of accuracy is lower than the second level of accuracy, and the first level of power consumption is lower than the second level of power consumption.

Optionally, the power on/off module may further include an output sub-module, which, when powered on, receives an output signal from the enable voltage comparison sub-module, eliminates fluctuations therein and outputs a power on/off signal,
wherein the startup sub-module is also configured to, if the first power-on condition is satisfied, convert the external power supply to the internal power supply for directly or indirectly driving the output sub-module to cause it to be powered on, or if the first power-on condition is unsatisfied, directly or indirectly cut off power to the output sub-module.

Optionally, the startup sub-module may include a first determination unit and a power conversion unit,
wherein when connected to the external power supply, the power conversion unit operates in one of at least an inactive mode, where it outputs electric power at a level not exceeding the first level of power consumption, a partially active mode where it outputs electric power at a level exceeding the first level of power consumption and not satisfying at least power and voltage requirements of the functional modules, and a normally active mode, where it outputs electric power at a level satisfying the power and voltage requirements of the circuitry; and
wherein in absence of intervention from other control logic, the first determination unit determines at the first level of accuracy whether the signal at the power on/off enable terminal satisfies the first power-on condition, and if the first power-on condition is unsatisfied, drives the power conversion unit to switch it to the inactive mode, or if the first power-on condition is satisfied, drives the power conversion unit to switch it to the normally active mode, or otherwise, drives the power conversion unit to switch it to the partially active mode.

Optionally, the startup sub-module may further include a second determination unit with a power supply input terminal connected to an internal power supply output terminal of the power conversion unit, which always operates normally as long as the power conversion unit operates in the partially or normally active mode and as a power supply line between the power conversion unit and the second determination unit is not disconnected or isolated, wherein:
in absence of intervention from other control logic, the second determination unit determines whether the signal at the power on/off enable terminal satisfies the first power-on condition, and if the first power-on condition is unsatisfied, drives the power conversion unit to switch it to the inactive mode, or if the first power-on condition is satisfied, drive the power conversion unit to switch it to the normally active mode, or in the event of a power loss, does not interfere with operating mode switching of the power conversion unit; and
when the first determination unit drives the power conversion unit to switch it to the partially active mode and when the second determination unit drives the power conversion unit to switch it to the normally active mode, the power conversion unit is switched to the normally active mode.

Optionally, the startup sub-module may further include a shutdown unit with an input terminal connected to an output terminal of the power on/off module,
wherein when a power-off signal is output from the output terminal of the power on/off module, the shutdown unit disables control of the second determination unit over the power conversion unit.

Optionally, the enable voltage comparison sub-module may include a reference voltage generation unit and a third determination unit, wherein:
the reference voltage generation unit is configured to, when powered on, outputs a reference voltage at the second level of accuracy, which is configured based on the second power-on condition; and
the third determination unit, when powered on, directly or indirectly compares an output signal from the reference voltage generation unit with the signal at the power on/off enable terminal at the second level of accuracy, and when their amplitude relationship is inverted, causes a transition in its output signal.

Optionally, a first reference voltage or a second reference voltage may be output, wherein the reference voltage generation unit receives a signal indicating whether the circuitry is in a powered on mode or in a powered off mode;
when the reference voltage generation unit is powered on, the reference voltage generation unit outputs the second reference voltage if the circuitry is in the powered on mode, or outputs the first reference voltage if the circuitry is in the powered off mode; and
the first reference voltage is higher than the second reference voltage.

Optionally, the output sub-module may include a charge/discharge unit and an output unit, wherein:
the charge/discharge unit is configured to delay entry of the output signal from the enable voltage comparison sub-module into the output unit and filter out fluctuations therein; and
the output unit determines its own output signal based on at least the output signal from the enable voltage comparison sub-module.

Optionally, the output unit may determine its own output signal based on the output signal from the enable voltage comparison sub-module and the signal at the power on/off enable terminal.

Optionally, the output sub-module may further include an isolation unit configured to isolate the internal components of the enable voltage comparison sub-module from interference with the charge/discharge unit and/or increase driving ability of the output signal from the enable voltage comparison sub-module.

Compared with the prior art, the present invention provides a power on/off module including a power on/off enable terminal, a startup sub-module and an enable voltage comparison sub-module. The startup sub-module determines, at both a low level of accuracy and a low level of power consumption, whether a signal at the power on/off enable terminal satisfies a power-on condition, and starts or stops supplying power to other modules according to predefined logic. After being powered on, the enable voltage comparison sub-module determines at a high level of accuracy whether the signal at the power on/off enable terminal satisfies the power-on condition and activates or deactivates the other modules according to the predefined logic. Standby power consumption of the startup sub-module is lower than a minimum level of power consumption necessary for normal operation of the enable voltage comparison sub-module. In this way, the operational characteristics of the individual sub-modules are sensibly exploited to achieve a good tradeoff between power-off power consumption and response accuracy that the prior art fails to provide.

### BRIEF DESCRIPTION OF THE DRAWINGS

Those of ordinary skill in the art will understand that the following drawings are presented to enable a better understanding of the present invention and not intended to limit the scope thereof in any sense, in which:

FIG. 1 is a schematic diagram showing the structure of a power on/off module according to an embodiment of the present invention;

FIG. 2 is a circuit diagram of a power on/off module according to an embodiment of the present invention; and FIG. 3 shows waveforms according to an embodiment of the present invention.

### LIST OF REFERENCE NUMERALS

1 power on/off enable terminal; 2 startup sub-module; 3 enable voltage comparison sub-module; 4 output sub-module;
21 first determination unit; 22-power conversion unit; 23 internal power supply output terminal; 24 second determination unit; 25 shutdown unit; 31 reference voltage generation unit; 32 third determination unit; 33 signal conversion unit; 41 isolation unit; 42 charge/discharge unit; 43 output unit.

### DETAILED DESCRIPTION

Objectives, features and advantages of the present invention will become more apparent upon reading the following description with reference to the accompanying drawings, which illustrates specific embodiments thereof. Note that the figures are provided in a very simplified form not necessarily drawn to exact scale for the only purpose of helping to explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents. The term “or” is generally employed in the sense of “and/or”, “several” of “at least one” and “at least two” of “two or more”. In addition, the terms “first”, “second” and “third” are intended only for illustration and are not to be construed as denoting or implying relative importance, or as implicitly indicating the numerical number of the referenced items. Accordingly, defining an item with “first”, “second” or “third” is an explicit or implicit indication of the presence of one or at least two such items. The terms “one end” and “other end”, as well as “proximal end” and “distal end”, are used to generally refer to opposing ends including the opposing endpoints, rather than only to the endpoints. As used herein, the terms “mounting”, “coupling”, “connecting” and any variants thereof should be interpreted in a broad sense. For instance, a connection may be a permanent, detachable or integral connection, or a mechanical or electrical connection, or a direct or indirect connection with one or more intervening media, or an internal communication or interaction between two elements. When an element is referred herein to as being “disposed on” another element, this is generally intended to only mean that there is a connection, coupling, engagement or transmission between the two elements, which may be either direct or indirect with one or more intervening elements, and should not be interpreted as indicating or implying a particular spatial position relationship between the two elements, i.e., the element may be located inside, outside, above, under, beside, or at any other location relative to the other element, unless the context clearly dictates otherwise. Those of ordinary skill in the art can understand the specific meanings of the above-mentioned terms herein, depending on their context.

In principle, the present invention seeks to provide a power on/off module, which overcomes the above-described problem with the prior art, i.e., it fails to provide both low power consumption and accurate response to a power-on signal in a powered off mode.

Description is set forth below with reference to the accompanying drawings.

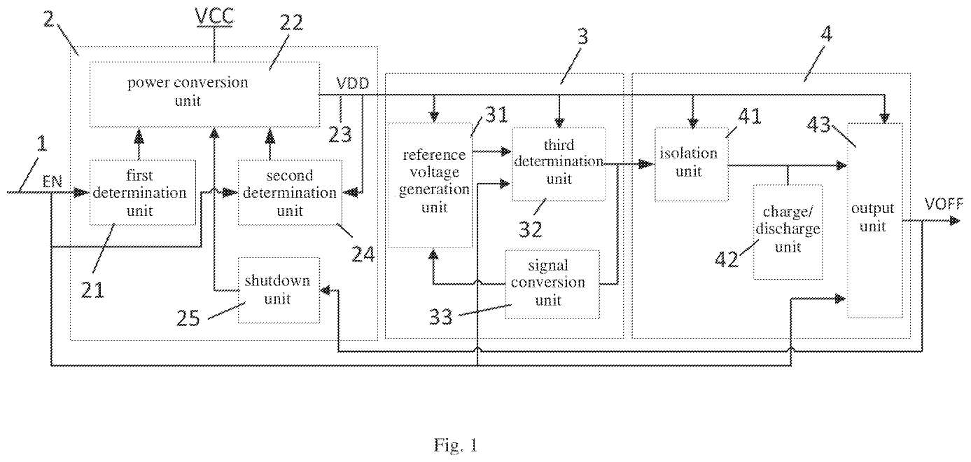

Referring to FIG. 1, the present invention provides a power on/off module used in circuitry including functional modules (not shown) in addition to the power on/off module. The power on/off module includes a power on/off enable terminal 1, a startup sub-module 2 and an enable voltage comparison sub-module 3. This power on/off module can be used in circuitries in various applications, and the functional modules are not limited to any particular functions.

The startup sub-module 2 is configured to receive an external power supply VCC.

The startup sub-module 2 determines, at a first level of accuracy, whether a signal EN at the power on/off enable terminal 1 satisfies a first power-on condition. If the first power-on condition is satisfied, it converts the external power supply VCC to an internal power supply VDD for directly or indirectly driving the enable voltage comparison sub-module 3 and the functional modules to cause them to be powered on. If the first power-on condition is unsatisfied, it directly or indirectly cuts off power to the enable voltage comparison sub-module 3 and the functional modules. Here, the term “driving” is intended to mean that the modules are caused to output control signals and to encompass scenarios where the purpose is not eventually achieved due to some reasons (e.g., the intervention of higher-level control logic, a circuit failure, etc.) This definition applies hereinafter.

The first power-on condition may be that a voltage at the enable terminal exceeds a specified value. For ease of understanding, in the present embodiment, the first power-on condition may be that the voltage is approximately >1.4 V (which is equal to VD1+VT1, the relevant meanings of VD1 and VT1 is described in detail below).

After being powered on, the enable voltage comparison sub-module 3 determines at a second level of accuracy whether the signal EN at the power on/off enable terminal 1 satisfies a second power-on condition. If the second power-on condition is satisfied, it outputs a control signal for driving at least some of the functional modules to cause them to be powered on. If the second power-on condition is unsatisfied, it outputs a control signal for driving at least some of the functional modules to cause them not to be powered on or remain OFF. In this application, the first level of accuracy is on the order of 0.1 V, and the second level of accuracy is on the order of 0.01 V.

For ease of understanding, in the present embodiment, the second power-on condition is that the voltage is >1.6 V.

Ideally, design details of the circuitry include: starting it if the signal EN is >1.6 V, or not if the signal EN is <1.6 V, in an OFF state. Description of logic for shutting the circuitry down in an ON state is set forth below.

However, in practical circumstances, the circuitry, no matter what form it assumes, would not be able to switch its operation exactly when the signal crosses 1.6 V. Instead, it typically operates according to the following logic: it is started when EN>b, or not when EN<a. When a<EN<b, its operation would be uncontrollable and unpredictable. The size of the interval [a, b] is also known as response accuracy, and a smaller value of this size means higher accuracy.

In view of the above, the present embodiment configures the first and second power-on conditions. The first power-on condition is that the voltage is >1.4 V, and the second power-on condition includes: the circuitry is powered on if the voltage is >1.6 V, or not, otherwise.

It will be understood that the specific values, i.e., 1.6 V and 1.4 V, are presented hereinabove only for the purpose of exemplification and may be modified by changing parameters of related elements.

It will be understood that, in other embodiments, it is also possible to configure the first and second power-on conditions as the same.

When the first power-on condition is unsatisfied, the startup sub-module 2 delivers its determination function at a first level of power consumption. After being powered on, the enable voltage comparison sub-module 3 delivers its determination function at a second level of power consumption. In this application, the first and second levels of power consumption may be measured by the magnitude of respective currents. The first level of power consumption is on the order of pA to nA, and the second level of power consumption is on the order of μA.

The first level of accuracy is lower than the second level of accuracy, and the first level of power consumption is lower than the second level of power consumption.

It will be understood that, in the present embodiment, it is not considered that lower accuracy necessarily means lower power consumption. Instead, it is considered that lower accuracy allows a wider range of elements and structure options, from which those with lower power consumption can be selected despite their low-accuracy response. That is, lower accuracy means more options, and those with lower power consumption may be selected.

With this in mind, according to the present embodiment, startup of the circuitry is divided into two separate stages: power-on of the modules; and their receipt of power-on signals. The two stages are controlled at different levels of accuracy by the modules operating at different levels of power consumption. Additionally, when the circuitry is powered off, the internal power supply is cut off, and its power consumption depends only on the startup sub-module 2 and is thereby lowered at the structural level. Further, lowering the accuracy of the startup sub-module 2 results in an additional reduction in power consumption, while the overall accuracy of the power on/off module is still ensured by the enable voltage comparison sub-module 3. In this way, low power consumption and accurate response to a power-on signal are both achieved in the powered off mode.

With continued reference to FIG. 1, the power on/off module further includes an output sub-module 4, which, when powered on, receives an output signal from the enable voltage comparison sub-module 3, eliminates fluctuations therein and outputs it as a power on/off signal.

The startup sub-module 2 is also configured to: if the first power-on condition is satisfied, convert the external power supply VCC to the internal power supply VDD, which directly or indirectly drives the output sub-module 4 and causes it to be powered on; or if the first power-on condition is unsatisfied, directly or indirectly cut off power to the output sub-module 4.

With this arrangement, the output signal is optimized and avoided from fluctuating around a critical value, which may lead to frequent switching of the circuitry,

Based on the inventive concept discussed above, those skilled in the art can implement the startup sub-module 2, the enable voltage comparison sub-module 3 and the output sub-module 4 with various functional units.

FIG. 1 shows a preferred implementation, in which the startup sub-module 2 includes a first determination unit 21 and a power conversion unit 22.

When connected to the external power supply VCC, the power conversion unit 22 can operate in one of at least three modes: inactive, partially active and normally active. In the inactive mode, the power conversion unit 22 outputs electric power at a level not exceeding the first level of power consumption. In the partially active mode, the power conversion unit 22 outputs electric power at a level exceeding the first level of power consumption and not satisfying at least power and voltage requirements of the functional modules. In the normally active mode, the power conversion unit 22 outputs electric power at a level satisfying the power and voltage requirements of the circuitry.

In the absence of intervention from other control logic, the first determination unit 21 determines at the first level of accuracy whether the signal EN at the power on/off enable terminal 1 satisfies the first power-on condition. If the first power-on condition is unsatisfied, it drives the power conversion unit 22 and switches it to the inactive mode. If the determination lies between satisfaction and unsatisfaction of the first power-on condition, it drives the power conversion unit 22 and switches it to the partially active mode. If the first power-on condition is unsatisfied, it drives the power conversion unit 22 and switches it to the normally active mode.

By “the determination lies between satisfaction and unsatisfaction of the first power-on condition”, it is intended to mean that, due to limited determination accuracy of the first determination unit 21, correctness of the determination cannot be guaranteed. This expression implies that the first determination unit 21 is an analog determination logic circuit.

It will be understood that operation of the power conversion unit 22 in the partially active mode is a technique feature dedicated to the first level of accuracy. If operating mode options for the power conversion unit 22 do not include the partially active mode, then it will mean that the power conversion unit 22 must be provided with additional logic and means, which enable the power conversion unit 22 to operate like a digital circuit. Therefore, the ability of the power conversion unit 22 to operate in the partially active mode does not necessarily mean that the startup sub-module 2 consumes less power, but provides it with more power consumption options, from which one allowing it to consume less power may be selected.

The partially active mode may introduce limitations to operating efficiency of the circuitry. Accordingly, in a preferred embodiment, the startup sub-module 2 further includes a second determination unit 24, the second determination unit 24 has a power supply input terminal connected to an internal power supply output terminal 23 of the power conversion unit 22. When the power conversion unit 22 operates in the partially or normally active mode, the second determination unit 24 can operate normally, as long as a power supply line between the power conversion unit 22 and the second determination unit 24 is not disconnected or isolated. In other words, power consumption of the second determination unit 24 in normal operation is higher than the first level of power consumption and lower than power consumption of the circuitry when it is operating normally.

In absence of intervention from other control logic, the second determination unit 24 determines whether the signal EN at the power on/off enable terminal 2 satisfies the first power-on condition. If the first power-on condition is unsatisfied, it drives the power conversion unit 22 and switches it to the inactive mode. If the first power-on condition is satisfied, it drives the power conversion unit 22 and switches it to the normally active mode. In the event of a power loss, the second determination unit 24 does not interfere with operating mode switching of the power conversion unit 22. That is, determination accuracy of the second determination unit 24 is actually higher than the first level of accuracy. When the determination of the first determination unit 21 lies between satisfaction and unsatisfaction of the first power-on condition, the second determination unit 24 may determine that the first power-on condition is satisfied. These different determinations are not contradictory, but occur due to the different levels of accuracy.

If the power conversion unit 22 and the second determination unit 24 are regarded as a whole and collectively referred to as a power supply component, then this power supply component will behave with the absence of a partially active mode.

Here, particular reference is made to control priority of the first determination unit 21 and the second determination unit 24. If the first determination unit 21 drives the power conversion unit 22 to switch it to the partially active mode while the second determination unit 24 drives the power conversion unit 22 to switch it to the normally active mode, then the power conversion unit 22 is eventually switched to the normally active mode.

In order to achieve efficiency shutdown, the startup sub-module 2 further includes a shutdown unit 25, the shutdown unit 25 has an input terminal connected to an output terminal of the power on/off module.

Once a power-off signal is output from the output terminal of the power on/off module, the shutdown unit 25 disables the control of the second determination unit 24 over the power conversion unit 22. At the same time, the power conversion unit 22 is switched to the partially active mode. This can accelerate the shutdown process.

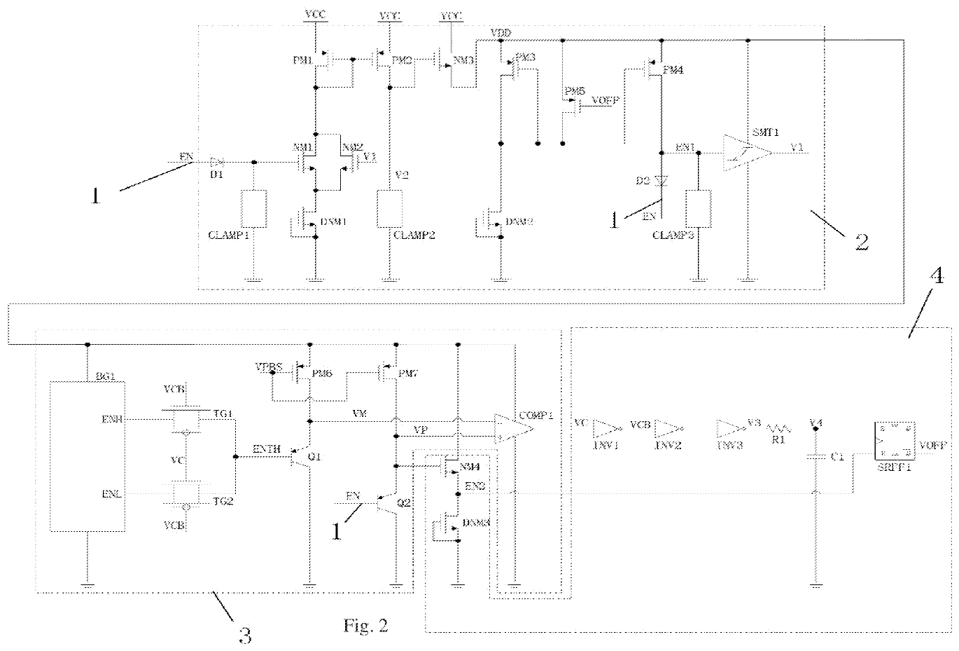

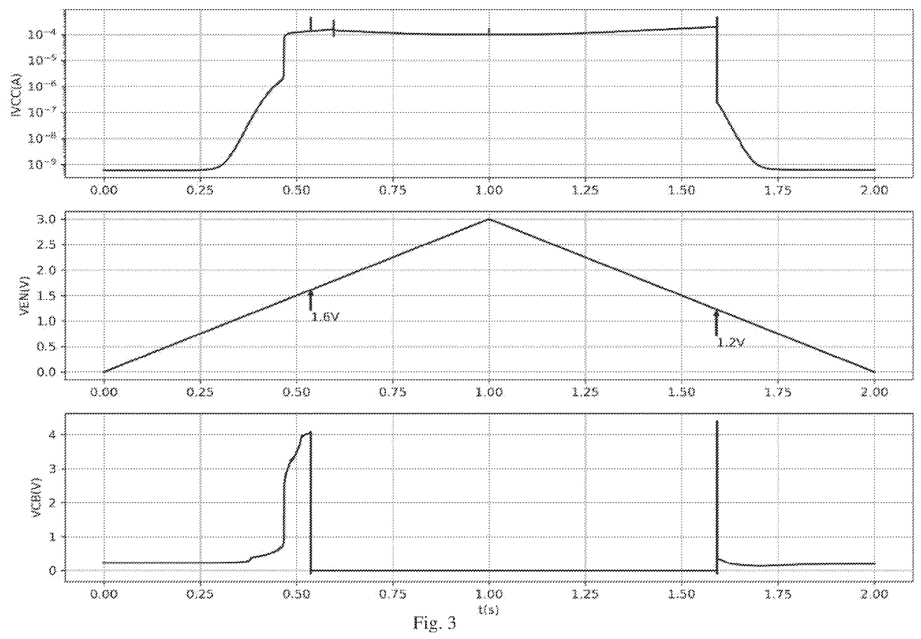

Those skilled in the art can configure suitable circuits for performing the functions of the various units described above. A preferred implementation is shown in FIG. 2.

Referring to FIG. 2, the startup sub-module 2 includes a first diode DI, a second diode D2, a first enhancement-type PMOS transistor PM1, a second enhancement-type PMOS transistor PM2, a third enhancement-type PMOS transistor PM3, a fourth enhancement-type PMOS transistor PM4, a fifth enhancement-type PMOS transistor PM5, a first enhancement-type NMOS transistor NM1, a second enhancement-type NMOS transistor NM2, a third enhancement-type NMOS transistor NM3, a first depletion-type NMOS transistor DNM1, a second depletion-type NMOS transistor DNM2, a first voltage clamping circuit CLAMP1, a second voltage clamping circuit CLAMP2, a third voltage clamping circuit CLAMP3 and a Schmitt trigger SMT1.

The first, second and third voltage clamping circuits CLAMP1, CLAMP2, CLAMP3 are each configured to try to sink a small current typically of 1 μA or smaller. If this fails, a very low voltage that is almost 0 V will be present across its terminals, If a current larger than the aforementioned value flows in, it can clamp the voltage across its terminals so that it does not change much even if the sink current varies vigorously (e.g., the voltage may change by less than 1 V in spite of that the sink current may vary within the range of 1 μA to 100 μA). Such a circuit can be implemented in various ways, and the simplest implementation would be a voltage regulator diode connected in parallel to a large resistor.

A depletion-type NMOS transistor has a threshold voltage VT lower than 0 V and therefore can source a current at its drain once its GATE and SOURCE terminals are connected together. The magnitude of the source current depends on the transistor's width-to-length aspect ratio. DNM1 to DNM3 of FIG. 2 can be each taken as a current source. In less demanding applications, or if the process does not allow, it is also possible to replace the first, second and third depletion-type NMOS transistors DNM1, DNM2, DNM3 (DNM3 belongs to the enable voltage comparison sub-module 3, as described below) with resistors.

How the above components are connected can be understood with reference to FIG. 2 and therefore need not be described here for the sake of brevity.

The first diode D1, the first voltage clamping circuit CLAMP1 and the first enhancement-type NMOS transistor NMI make up the first determination unit 21. The first enhancement-type PMOS transistor PM1, the second enhancement-type PMOS transistor PM2, the third enhancement-type PMOS transistor PM3, the first depletion-type NMOS transistor DNM1, the second depletion-type NMOS transistor DNM2, the second voltage clamping circuit CLAMP2 and the third enhancement-type NMOS transistor NM3 make up the power conversion unit 22. A source of the third enhancement-type NMOS transistor NM3 is configured as the internal power supply output terminal 23. The second enhancement-type NMOS transistor NM2, the fourth enhancement-type PMOS transistor PM4, the second diode D2, the third voltage clamping circuit CLAMP3 and the Schmitt trigger SMT1 make up the second determination unit 24. The fifth enhancement-type PMOS transistor PM5 serves as the shutdown unit.

Operation of the startup sub-module 2 is described below.

When the voltage at the EN pin is much lower than VD1+VT1, NM1 is not turned on, where VD1 represents a forward voltage drop across the first diode D1 (the first diode D1 may be implemented otherwise, for example, replaced with a body diode of a MOS transistor), and VT1 represents the turn-on threshold voltage of NM1. The VGS1 voltage of the high-voltage NMOS transistor NM1 is lower than its turn-on voltage VT1. Moreover, if the voltage at the V1 terminal (i.e., a gate of NM2, or an output terminal of the Schmitt trigger SMT1) is also lower than a turn-on voltage VT2 of the high-voltage NMOS transistor NM2, NM2 will not be turned on. Accordingly, the high-voltage PMOS transistor PM1, and hence PM2 that is of the same type as PM1 and makes up a current mirror together therewith, will also not be turned on. Consequently, the GATE terminal of the high-voltage NMOS transistor NM3 is pulled by CLAMP2 to a very low voltage, causing NM3 not to be turned on. Thus, when the voltage at the EN pin is at a low level, no current can flow from the VCC terminal into the startup sub-module 2, making it operate at an almost zero current (except for leakage currents from the components, which are typically ignorable) and consume very little power.

When the voltage at the EN pin rises to a level slightly higher than VD1+VT1 (corresponding to a determination made by the first determination unit 21 lying between satisfaction and unsatisfaction of the first power-on condition), NM1 starts being turned on, and PM1 and PM2 starts being slight turned on (on the order of nA), However, the current through PM2 is not large enough to support operation of CLAMP2. Consequently, the voltage across CLAMP2 remains low. NM3 is not turned on, and the downstream circuit portion is not powered.

As the voltage at the EN pin rises, the current through NM1 increases, and hence those through PM1 and PM2. When the current ramps to a level that is large enough to drive CLAMP2, and if the VGS voltage of NM3 is higher than VT3 (the turn-on threshold of NM3; the back-gate effect is ignored here) at this time, NM3 starts being turned on (at this point, the first determination unit 21 will still make a determination lying between satisfaction and unsatisfaction of the first power-on condition).

The power supply voltage VDD for powering the downstream circuit modules, which is typically lower than 5 V, is present at the SOURCE terminal of NM3. The depletion-type NMOS transistor DNM2 serves as a current source for setting an operating current for the low-voltage PMOS transistor PM3. PM4 and PM3 make up a current mirror, and PM4 is also configured to provide the diode D2 with a bias current. If PM5 is not taken into account, the ENI voltage will increase with the VEN voltage, and they satisfy VEN1=VEN+VD2. When VENI rises to a threshold voltage of the Schmitt trigger SMT1, V1 outputs a high level, which causes NM2 to be fully turned on. That is, as soon as VEN exceeds VT1+VD1, operation of this circuit will be stabilized. Upper limits of currents through NM1, PM1 and PM2 are set by DNM1, and the GATE voltage of NM3 and the VDD voltage are determined by a voltage V2 clamped by CLAMP2. The VDD voltage can be roughly expressed as VDD=V2−VT3 (with a gate-overdrive voltage of NM3 and the back-gate effect being ignored). These current and voltage limits can avoid the circuit from operating beyond its specified ranges, which may cause damage.

PM5 is configured to turn off the current mirror made up of PM3 and PM4. In normal operation, PM5 is not turned off under the control of an output signal VOFF from the power on/off module, which is at a high level. In order to shut down the power conversion unit 22, VOFF is caused to transition to a low level, turning on PM5. Consequently, no currents flow through PM3 and PM4, and the power conversion unit 22 is swiftly shut down.

With continued reference to FIG. 1, the enable voltage comparison sub-module 3 includes a reference voltage generation unit 31 and a third determination unit 32.

When powered up, the reference voltage generation unit 31 is configured to provide a reference voltage at the second level of accuracy. The reference voltage is configured based on the second power-on condition.

When powered up, the third determination unit 32 directly or indirectly compares the output signal from the reference voltage generation unit with the signal EN at the power on/off enable terminal at the second level of accuracy. When their amplitude relationship is inverted, the third determination unit 32 causes a transition in its output signal. For example, when the former is higher than the latter, the third determination unit 32 may output a high level. However, when the former becomes lower than the latter, the third determination unit 32 may instead output a low level. When the two are equal to each other, the component may be arbitrarily configured according to its own characteristics.

In order to prevent the circuitry from fluctuating under some circumstances, the reference voltage generation unit 31 may provide both a first reference voltage and a second reference voltage. The reference voltage generation unit 31 may receive a signal indicating whether the circuitry is being ON or OFF. For example, in the embodiment of FIG. 1, the reference voltage generation unit 31 may receive the output signal from the third determination unit 32 through a signal conversion unit 33. In alternative embodiments, it may receive the output signal from the power on/off module as a basis for making a determination.

After being powered up, if the circuitry is being ON, then the reference voltage generation unit 31 may output the second reference voltage. Otherwise, if the circuitry being OFF, then it may output the first reference voltage.

The first reference voltage is higher than the second reference voltage.

In one embodiment, the first reference voltage is 1.6 V, and the second reference voltage is 1.2 V.

Referring to FIG. 2, the enable voltage comparison sub-module 3 includes a bandgap reference voltage component BG1, a first transmission gate TG1, a second transmission gate TG2, a first PNP-type transistor Q1, a second PNP-type transistor Q2, a sixth enhancement-type PMOS transistor PM6, a seventh enhancement-type PMOS transistor PM7 and a comparator COMP1. The first transmission gate TG1 is configured so that, when a high level is received at its high-level enable terminal and a low level at its low-level enable terminal, its circuit between its input and output terminals is turned on. Otherwise, the circuit between the input and output terminals is turned off. The second transmission gate TG2 operates in the same way as the first transmission gate TG1.

The enable voltage comparison sub-module 3 also includes a first inverter INV1. Although the first inverter INV1 is shown in FIG. 2 as belonging to the output sub-module 4, in the field of electrical technology, it is common and understandable that a single component commonly belongs to two functional sub-modules.

The bandgap reference voltage component BG1, the first transmission gate TG1 and the second transmission gate TG2 make up the reference voltage generation unit 31. The high-level enable terminal of the first transmission gate TG1 and the low-level enable terminal of the second transmission gate TG2 are connected to each other and together configured as a first control terminal of the reference voltage generation unit 31. The low-level enable terminal of the first transmission gate TG1 and the high-level enable terminal of the second transmission gate TG2 are connected to each other and together configured as a second control terminal of the reference voltage generation unit 31. The first transistor Q1, the second transistor Q2, the sixth enhancement-type PMOS transistor PM6, the seventh enhancement-type PMOS transistor PM7 and the comparator COMP1 make up the third determination unit 32. Gates of PM6 and PM7 are configured to receive a bias voltage VPBS, and in one embodiment, connected to a gate (not shown) of PM4.

The first inverter INV1 serves as the signal conversion unit 33. In alternative embodiments, the signal conversion unit 33 may be omitted, or the signal conversion function may be provided by the reference voltage generation unit 31.

The second control terminal of the reference voltage generation unit 31 is configured to receive the output signal VC from the comparator COMP1, and the first control terminal of the reference voltage generation unit 31 is configured to receive the inverted version VCB of the output signal VC from the comparator COMP1. The VCB signal may result from a conversion operation of the signal conversion unit 33.

In alternative embodiments, the bandgap reference circuit BG1 may be replaced with other reference voltage generation circuits operating according to different principles. The bandgap reference circuit can produce a stable reference voltage and current source. BG1 is powered by the power supply voltage VDD and outputs two voltage sources, namely, the first reference voltage ENH and the second reference voltage ENL. ENH is higher than ENL. ENH is configured to set a power-on voltage for the system, while ENL is configured to set a power-off voltage for the system.

The transmission gates TG1 and TG2 are controlled by the signal VC and its inverted version VCB, respectively. When VC is high and VCB is low, TG2 is turned on and TG1 off, and therefore VENTH=VENL. On the contrary, when VC is low and VCB is high, TG1 is turned on and TG2 off, and therefore VENTH=VENH. VENTH represents a voltage at the output terminal of the reference voltage generation unit 31. PM6 and PM7 are low-voltage PMOS transistors of the same type and together make up a current mirror with VPBS as its bias voltage source. In alternative embodiments, this signal may also be produced by a conventional biasing technique, or received from a GATE terminal of another PMOS transistor in a current mirror, such as PM4. Q1 and Q2 are PNP transistors of the same size, and PM6 and PM7 serve to provide Q1 and Q2 with bias currents. Since equal currents flow through Q1 and Q2, and because Q1 and Q2 are of the same size and type, it can be considered that VEB1 of Q1 is equal to VEB2 of Q2, i.e., VEB1=VEB2=VEB.

Thus, VM=VENTH+VEB, and VP=VEN+VEB, where VM represents a voltage at an inverting terminal of the comparator COMP1, and VP is a voltage at a non-inverting terminal of the comparator COMP1.

As can be seen from the above analysis, when VP is higher than VM, VEN is higher than VEHTH, and vice versa.

The comparator COMP1 is configured to draw a voltage comparison between VP and VM. When VP is higher than VM (i.e., VEN is higher than VENTH), VC is high, Otherwise, it is low. Notably, in alternative embodiments, if required, the comparator COMP1 may be arranged at a different location, and its non-inverting and inverting terminals may be otherwise wired. FIG. 2 shows only one possible implementation.

When VEN is higher than VENH, the power on/off module outputs the power-on signal for turning on the functional modules in the circuitry. When VEN is lower than VENL, the power on/off module outputs the power-off signal for turning off this circuit and the other modules in the circuitry so that there is almost no current in the OFF state. When VEN lies between VENL and VENH, the system does nothing and continues its current operation. This window between VENH and VENL can effectively avoid false triggering. Further, there may be a margin between VENH and (VD1+VT1), and typically VENH>=1.6 V. Likewise, there may also be a margin between VENL and (VD1+VT1), and typically VENL<=1.2 V.

Since VENL and VENH are both produced by the bandgap reference circuit, they are relatively accurate. Moreover, since Q1 and Q2 are provided with equal bias currents and of the same type, the VEB's of Q1 and Q2 can be considered equal. Therefore, high-accuracy enable control voltages can be provided.

With continued reference to FIG. 1, the output sub-module 4 further includes a charge/discharge unit 42 and an output unit 43.

The charge/discharge unit 42 is configured to delay the provision of the output signal from the enable voltage comparison sub-module 3 to the output unit 43 and filter out fluctuations in the enable voltage comparison sub-module 3.

The output unit 43 determines its own output signal based on at least the output signal from the enable voltage comparison sub-module 3.

Additionally, the output unit 43 may determine its own output signal based on the output signal from the enable voltage comparison sub-module 3 and the signal EN at the power on/off enable terminal. This can additionally increase the accuracy of the power on/off module and prevent an erroneous action that may arise from a sudden change in the single signal that serves as the basis.

Preferably, the output sub-module 4 further includes an isolation unit 41, the isolation unit 41 is used for isolating the components of the enable voltage comparison sub-module 3 from interference from the charge/discharge unit 42 and/or for augmenting the driving ability of the output signal from the enable voltage comparison sub-module 3.

With continued reference to FIG. 2, the output sub-module 4 includes the seventh enhancement-type PMOS transistor PM7, a fourth enhancement-type NMOS transistor NM4, a third depletion-type NMOS transistor DNM3, the second transistor Q2, the first inverter INV1, a second inverter INV2, a third inverter INV3, a charge/discharge resistor R1, a charge/discharge capacitor C1, an SR flip-flop SRFF1 and a power-on reset (POR) component (not shown). The first inverter INV1, the second inverter INV2, the third inverter INV3 and the SR flip-flop SRFF1 are powered by VDD (not shown). Q2 and PM7 are common to the enable voltage comparison sub-module 3 and the output sub-module 4.

The first inverter INV1, the second inverter INV2 and the third inverter INV3 make up the isolation unit 41. The charge/discharge resistor R1 and charge/discharge capacitor Cl make up the charge/discharge unit 42. The seventh enhancement-type PMOS transistor PM7, the fourth enhancement-type NMOS transistor NM4, the third depletion-type NMOS transistor DNM3, the second transistor Q2, the POR component and the SR flip-flop SRFF1 make up the output unit 43. A base terminal of the second transistor Q2 is configured as one input terminal of the output unit 43, and an inverting output terminal of the SR flip-flop SRFF1 is configured as an output terminal of the output unit 43.

Operating logic of the SR flip-flop SRFF1 can be understood according to the common general knowledge in the art and therefore need not be described in detail herein.

In the present embodiment, the output unit 43 utilizes some of the components in the enable voltage comparison sub-module 3 to acquire the signal EN at the power on/off enable terminal. In alternative embodiments, a separate input terminal may be provided for receiving the signal EN from the power on/off enable terminal.

In alternative embodiments, the isolation unit 41 may be otherwise configured, or omitted if this is confirmed to be feasible.

NM4 is a low-voltage enhancement-type NMOS transistor, and NM3 and the depletion-type NMOS transistor DNM3 are configured to produce a voltage EN2 for used by subsequent stages. VEN2=VEN+VEB2−VT4 is satisfied, where VT4 represents a turn-on threshold voltage of NM4. Generally, VEN2 is slightly lower than VEN, with the difference therebetween typically lying between about 0.1 and 0.3 V.

R1 and C1 make up a charge circuit for enabling delayed power-off. Its RC time constant can be adjusted to change the time period from power-off being triggered by VEN to actual power-off of the circuitry. When VEN is lower than VENTH, VC is low, and V3 is high. Consequently, C1 is charged for a certain period of time through R1, causing V4 to rise. When V4 reaches a threshold of the SR flip-flop, an S terminal of SRFF1 transitions high. At this point, since EN2 is low, the output VOFF of the SR flip-flop SRFF1 is low, turning on PM5 in STAGE1. At the same time, no current flows through PM4, decreasing EN1. Consequently, V1 is low, and NM2 is not turned on. Since VENL is lower than VD+VT1, NM1 is also not turned on. Thus, the system is fully powered off.

The POR component is used to prevent the SR flip-flop from experience abnormalities at an initial stage. Under the effect of the POR component, the SR flip-flop, once powered on, initially outputs a high level at its inverting output terminal.

FIG. 3 shows operating waveforms according to an embodiment of the present invention, in which the upper waveform represents a current flowing from VCC to the circuitry, the middle one is the voltage at the EN pin, and the bottom one shows the output signal VCB of the first inverter INV1. It can be considered that VCB reflects VOFF.

From FIG. 3, it can be seen that, when the voltage VEN at the EN pin is much lower than VD1+VT1 (0 s to 0.25 s and 1.75 s to 2 s), the current from VCC is smaller than 1 nA, enabling almost zero-current operation in the powered off mode.

During a rise of VEN, when it reaches about 1.4 V, the internal circuits start operating, as manifested by a surge of IVCC. However, as VEN is still below 1.6 V, i.e., the specified VENH value, the power-off signal VCB is high. Under the control of this signal, the functional modules are turned or maintained OFF. When VEN rises to1.6 V, VCB transitions low and no longer provides a power-off indication.

During a drop of VEN, when it reaches about 1.2 V, i.e., the specified VEHL value, VCB transitions and remains high for a short while, indicating that the power-off threshold has been reached. After that, the circuitry is overall shutdown, accompanied by a sharp drop of the current IVCC from VCC. Thus, the circuitry is powered off.

As can be seen from FIG. 3, the present embodiment can behave just as designed to provide good performance in terms of both power consumption and response accuracy.

In summary, embodiments of the present invention provide a power on/off module including a power on/off enable terminal, a startup sub-module and an enable voltage comparison sub-module. The startup sub-module determines, at both a low level of accuracy and a low level of power consumption, whether a signal at the power on/off enable terminal satisfies a power-on condition, and starts or stops supplying power to other modules according to predefined logic. After being powered on, the enable voltage comparison sub-module determines at a high level of accuracy whether the signal at the power on/off enable terminal satisfies the power-on condition and activates or deactivates the other modules according to the predefined logic. Standby power consumption of the startup sub-module is lower than a minimum level of power consumption necessary for normal operation of the enable voltage comparison sub-module. In this way, the operational characteristics of the individual sub-modules are sensibly exploited to achieve a good tradeoff between power-off power consumption and response accuracy that the prior art fails to provide.

The description presented above is merely that of a few preferred embodiments of the present invention and does not limit the scope thereof in any sense. Any and all changes and modifications made by those of ordinary skill in the art based on the above teachings fall within the scope as defined in the appended claims.

1. A power on/off module for use in circuitry, the circuitry comprising the power on/off module and functional modules, the power on/off module comprising a power on/off enable terminal, a startup sub-module and an enable voltage comparison sub-module, wherein:
the startup sub-module is configured to obtain an external power supply;
the startup sub-module determines at a first level of accuracy whether a signal at the power on/off enable terminal satisfies a first power-on condition, and if the first power-on condition is satisfied, converts the external power supply into an internal power supply for directly or indirectly driving the enable voltage comparison sub-module and the functional modules to cause the enable voltage comparison sub-module and the functional modules to be powered on, or if the first power-on condition is unsatisfied, directly or indirectly cuts off power to the enable voltage comparison sub-module and the functional modules;
the enable voltage comparison sub-module, once powered on, determines at a second level of accuracy whether the signal at the power on/off enable terminal satisfies a second power-on condition, and if the second power-on condition is satisfied, outputs a control signal for driving at least some of the functional modules to cause the at least some of the functional modules to be powered on, or if the second power-on condition is unsatisfied, outputs a control signal for driving at least some of the functional modules to cause the at least some of the functional modules not to be powered on or remain off;
when the first power-on condition is not satisfied, the startup sub-module delivers its determination function at a first level of power consumption, and the enable voltage comparison sub-module, when powered on, delivers its determination function at a second level of power consumption; and
the first level of accuracy is lower than the second level of accuracy, and the first level of power consumption is lower than the second level of power consumption.

2. The power on/off module according to claim 1, further comprising an output sub-module, when the output sub-module is powered on, the output sub-module receives an output signal from the enable voltage comparison sub-module, eliminates fluctuations therein and outputs a power on/off signal,
wherein the startup sub-module is also configured to, if the first power-on condition is satisfied, convert the external power supply to the internal power supply for directly or indirectly driving the output sub-module to cause the output sub-module to be powered on, or if the first power-on condition is unsatisfied, directly or indirectly cut off power to the output sub-module.

3. The power on/off module according to claim 1, wherein the startup sub-module comprises a first determination unit and a power conversion unit, wherein:
when connected to the external power supply, the power conversion unit operates in one of at least an inactive mode, a partially active mode and a normally active mode; in the inactive mode, the power conversion unit outputs electric power at a level not exceeding the first level of power consumption, in the partially active mode, the power conversion unit outputs electric power at a level exceeding the first level of power consumption and not satisfying at least power and voltage requirements of the functional modules, and in the normally active mode, the power conversion unit outputs electric power at a level satisfying the power and voltage requirements of the circuitry; and
in absence of intervention from other control logic, the first determination unit determines at the first level of accuracy whether the signal at the power on/off enable terminal satisfies the first power-on condition, and if the first power-on condition is unsatisfied, drives the power conversion unit to switch it to the inactive mode, or if the first power-on condition is satisfied, drives the power conversion unit to switch it to the normally active mode, or otherwise, drives the power conversion unit to switch it to the partially active mode.

4. The power on/off module according to claim 3, wherein the startup sub-module further comprises a second determination unit, the second determination unit having a power supply input terminal connected to an internal power supply output terminal of the power conversion unit, which always operates normally as long as the power conversion unit operates in the partially active mode or in the normally active mode and as a power supply line between the power conversion unit and the second determination unit is not disconnected or isolated;
in absence of intervention from other control logic, the second determination unit determines whether the signal at the power on/off enable terminal satisfies the first power-on condition, and if the first power-on condition is unsatisfied, drives the power conversion unit to switch it to the inactive mode, or if the first power-on condition is satisfied, drive the power conversion unit to switch it to the normally active mode, or in the event of a power loss, does not interfere with operating mode switching of the power conversion unit; and
when the first determination unit drives the power conversion unit to switch it to the partially active mode and when the second determination unit drives the power conversion unit to switch it to the normally active mode, the power conversion unit is switched to the normally active mode.

5. The power on/off module according to claim 4, wherein the startup sub-module further comprises a shutdown unit, the shutdown unit having an input terminal connected to an output terminal of the power on/off module,
wherein when a power-off signal is output from the output terminal of the power on/off module, the shutdown unit disables control of the second determination unit over the power conversion unit.

6. The power on/off module according to claim 1, wherein the enable voltage comparison sub-module comprises a reference voltage generation unit and a third determination unit, wherein:
when the reference voltage generation unit is powered on, the reference voltage generation unit is configured to output a reference voltage at the second level of accuracy, which is configured based on the second power-on condition; and
when the third determination unit is powered on, the third determination unit directly or indirectly compares an output signal from the reference voltage generation unit with the signal at the power on/off enable terminal at the second level of accuracy, and when their amplitude relationship is inverted, causes a transition in an output signal of the third determination unit.

7. The power on/off module according to claim 6, wherein the reference voltage comprises a first reference voltage and a second reference voltage, wherein the reference voltage generation unit receives a signal indicating whether the circuitry is in a powered on mode or in a powered off mode;
when the reference voltage generation unit is powered on, the reference voltage generation unit outputs the second reference voltage if the circuitry is in the powered on mode, or outputs the first reference voltage if the circuitry is in the powered off mode; and
the first reference voltage is higher than the second reference voltage.

8. The power on/off module according to claim 2, wherein the output sub-module comprises a charge/discharge unit and an output unit, wherein:
the charge/discharge unit is configured to delay entry of the output signal from the enable voltage comparison sub-module into the output unit and filter out fluctuations in the enable voltage comparison sub-module; and
the output unit determines its own output signal based on at least the output signal from the enable voltage comparison sub-module.

9. The power on/off module according to claim 8, wherein the output unit determines its own output signal based on the output signal from the enable voltage comparison sub-module and the signal at the power on/off enable terminal.

10. The power on/off module according to claim 8, wherein the output sub-module further comprises an isolation unit configured to isolate the internal components of the enable voltage comparison sub-module from interference with the charge/discharge unit and/or increase driving ability of the output signal from the enable voltage comparison sub-module.

11. The power on/off module according to claim 4, wherein the first determination unit comprises a first diode, a first voltage clamping circuit and a first enhancement-type NMOS transistor and wherein the power conversion unit comprises a first enhancement-type PMOS transistor, a second enhancement-type PMOS transistor, a third enhancement-type PMOS transistor, a first depletion-type NMOS transistor, a second depletion-type NMOS transistor, a second voltage clamping circuit and a third enhancement-type NMOS transistor.

12. The power on/off module according to claim 11, wherein a source terminal of the third enhancement-type NMOS transistor is configured as the internal power supply output terminal.

13. The power on/off module according to claim 5, wherein the second determination unit comprises a second enhancement-type NMOS transistor, a fourth enhancement-type PMOS transistor, a second diode, a third voltage clamping circuit and a Schmitt trigger, and wherein the shutdown unit comprises a fifth enhancement-type PMOS transistor, 14. The power on/off module according to claim 10, wherein the isolation unit comprises a first inverter, a second inverter and a third inverter, the charge/discharge unit comprising a charge/discharge resistor and a charge/discharge capacitor, and wherein the output unit comprises a seventh enhancement-type PMOS transistor, a fourth enhancement-type NMOS transistor, a third depletion-type NMOS transistor, a second transistor, a power-on reset (POR) component and an SR flip-flop.

15. The power on/off module according to claim 14, wherein a base terminal of the second transistor is configured as one input terminal of the output unit, and wherein an inverting output terminal of the SR flip-flop is configured as an output terminal of the output unit.
